(19) United States
(12) Patent Application Publication
(10) Pub. No.: US 2024/0248116 A1
(43) Pub. Date: Jul. 25, 2024

(54) TACTILE ELECTRICAL CONNECTION INDICATOR

(71) Applicant: Microsoft Technology Licensing, LLC, Redmond, WA (US)

(72) Inventors: Karsten AAGAARD, Monroe, WA (US); Suet Fong TIN, Redmond, WA (US); Chee Kiong FONG, Saratoga, CA (US); Michael Roy VOLKMAN, Port Townsend, WA (US); Geoffrey Jason SHEW, Redmond, WA (US)

(21) Appl. No.: 18/156,850

(22) Filed: Jan. 19, 2023

(51) Int. Cl. G01R 1/02; G01R 31/69

(52) U.S. Cl. CPC G01R 1/025; G01R 31/69

(57) ABSTRACT

For visually impaired users, LED indicators on electrical connectors are difficult or impossible to use. While LED indicators can provide quick and easy visual feedback to users without visual impairment, LED indicators are often problematic, even for those users without visual impairment. For example, placement and brightness of the LED is carefully planned so that the LED is easy to see but not too obtrusive. The presently disclosed technology is directed to tactile electrical connection indicators that supplement or replace the LED indicators on electrical connectors.

### BACKGROUND

Accessibility is the design of products, devices, services, vehicles, or environments so for users with various disabilities. Accessible product design and development is generally directed at direct (unassisted) access or indirect (assisted) access. In contrast to direct access, indirect access generally adopts assistive technology (e.g., computer screen readers) to provide access for a disabled user. Accessibility can be viewed as the “ability to access” and benefit from a system. Improving accessibility focuses on enabling access for people with disabilities or enabling access using assistive technology; however, improved accessibility often brings benefits to all users.

### SUMMARY

Implementations described herein provide an electrical connector comprising a connector housing, a set of electrical contacts within the connector housing and at a distal end of the electrical connector, a tactile indicator selectively moveable with reference to the connector housing, and a circuit board controlling an actuator. The actuator is connected to the tactile indicator and biases the tactile indicator to a first position with reference to the connector housing when the set of electrical contacts are disconnected. The actuator moves the tactile indicator to a second position with reference to the connector housing when the set of electrical contacts are connected.

Implementations described herein further provide a method of using an electrical connector comprising inserting a first part of the electrical connector including a plug extending from a connector housing at a distal end of a cable into a second part of the electrical connector including a recess in an electric device, establishing an electrical connection between a first set of electrical contacts on the plug and a second set of electrical contacts within the recess, the establishing operation responsive to the inserting operation, and actuating an actuator connected to a tactile indicator within the connector housing, the actuator to move the tactile indicator to a connected position with reference to the connector housing, the actuating operation responsive to the establishing operation.

Other implementations are also described and recited herein. This Summary is provided to introduce a selection of concepts in a simplified form that are further described below in the Detailed Descriptions. This Summary is not intended to identify key features or essential features of the claimed subject matter, nor is it intended to be used to limit the scope of the claimed subject matter.

### BRIEF DESCRIPTIONS OF THE DRAWINGS

FIG. 1A illustrates a partial perspective view of a computing device and associated cable with a disconnected electrical connector incorporating a tactile electrical connection indicator.

FIG. 1B illustrates a partial perspective view of the computing device and associated cable of FIG. 1A, with the electrical connector incorporating the tactile electrical connection indicator connected.

FIG. 2A illustrates a partial perspective view of an electrical connector incorporating a tactile electrical connection indicator in a disconnected position.

FIG. 2B illustrates a partial perspective view of the electrical connector incorporating the tactile electrical connection indicator of FIG. 2A in a connected position.

FIG. 3 illustrates a partial perspective view of an electrical connector incorporating a tactile electrical connection indicator and an enlarged and exploded view thereof.

FIG. 4 illustrates example operations for using an electrical connector incorporating a tactile electrical connection indicator.

### DETAILED DESCRIPTIONS

Electric devices convert electrical current into some other form of energy, such as light, heat, or motion, to produce a desired output. An electric device is one that directly uses electrical energy to perform a task. Electronic devices also convert electrical current into light, heat, or motion, but additionally uses the electrical current in a manner that adds meaningful information (data) to and/or extracts meaningful information (data) from the current. In sum, if a device uses electricity merely as energy, it is electrical. If the device additionally uses electricity as a medium for manipulating information (data), it is electronic. While electrical and electronic devices are different but overlapping categories of devices, electronic devices are a subset of electrical devices in that all electronic devices are electrical devices.

Electrical cables carry electricity and/or data between an electrical device (e.g., a computing device) and a source (e.g., a power supply or another electrical device). While an electrical device is any device powered by electricity, an electronic device (or computing device) may further include firmware and/or software for performing one or more arithmetic and/or logical operations. Electrical connectors provide electrical cables an ability to selectively connect to an electrical device. In various implementations, the electrical devices disclosed herein may be computing devices, such as tablet computers, laptop computers, personal computers, gaming devices, smart phones, or any other discrete devices that carries out one or more specific sets of arithmetic and/or logical operations. Electrical devices also include peripheral devices for a computing device, such as keyboards, mice, trackpads, trackballs, joysticks, and so on.

Electrical connectors often incorporate a light (e.g., a light-emitting diode (LED)) to visually indicate the status of an electric or electronic connection. For example, power cables often incorporate an LED indicator to visually confirm that a power is being supplied via the power cable. Further, the color of the LED indicator may indicate a state of charge of a connected battery (e.g., red may indicate discharge, yellow may indicate partially charged, and green may indicate fully charged. Still further, the LED may flash to indicate a charging state (e.g., a flashing light may indicate that charging is underway, while a solid light may indicate that charging is complete). The foregoing are merely examples of how an LED indicator may be used to various states of an electrical connection. Other visual indications on electrical connectors are contemplated herein.

For visually impaired users, visual indicators on electrical connectors are difficult or impossible to use. While some accessibility features within software on an electronic device may be helpful to communicate a status of an electric or electronic connection (e.g., via audio cues), these features may be obtrusive, lack continuous feedback, and require training to use. Further, if the electrical connector is not used with a device running software with accessibility features, or the device is in an off state, such software-based accessibility features may not be available.

While LED indicators can provide quick and easy visual feedback to users without visual impairment, LED indicators are often problematic, even for those users without visual impairment. For example, placement and brightness of the LED is carefully planned so that the LED is easy to see but not too obtrusive. This balance is difficult to achieve and maintain across a wide swath of users. Further, LED brightness is challenging when designing an electrical or electronic device for varying ambient lighting conditions.

The presently disclosed technology is directed to tactile electrical connection indicators that supplement or replace the aforementioned visual indicators on electrical connectors. As an alternative or supplement to LED-driven visual indicators, the presently disclosed electrical connection indicators provide tactile feedback to the user. Further, as an alternative to a purely mechanical visual indicator, the presently disclosed electrical connection indicators provide tactile feedback to the user confirming an electric connection, not merely that a mechanical connection has been achieved.

In various implementations, tactile electrical connection indicators may include a mechanical feature that protrudes from a connector housing when powered and recesses into the connector housing when unpowered. The tactile electrical connection indicators can work with LED-driven visual indicators to provide information about charging status to a user. Tactile electrical connection indicators address issues with LED-driven visual indicators including accessibility, variation in ambient lighting, and LED placement challenges.

In sum, tactile electrical connection indicators provide at least the following benefits. Tactile feedback is persistent, which permits a user to quickly check electrical connection status at any point in time by touching the electrical connector with their hand or other portion of their body. While the tactile electrical connection indicators discussed herein may be used most often with a user's hands and fingers, any portion of the user's body capable of touch sensation and physical placement on the tactile electrical connection indicators may utilize the tactile electrical connection indicators. Tactile electrical connection indicators do not require the availability of accessibility options or configuration of available accessibility options within an electrical device. Tactile electrical connection indicators work in all lighting conditions, which renders issues with LED brightness and sightlines (discussed above) moot. Tactile features adopted by the tactile electrical connection indicators can be “smart” by pulsing up and down at different intervals to relay various power conditions or cautions, for example.

Features of the tactile electrical connection indicators disclosed herein may be applied to any electrical connector for any electrical device, including purely electric device, electronic devices, and computing devices. Further, the tactile electrical connection indicators may be applied to vehicles (e.g., automobiles, watercraft, and aircraft), consumer electronics (e.g., cameras, telephones, and home appliances), and industrial or commercial machinery.

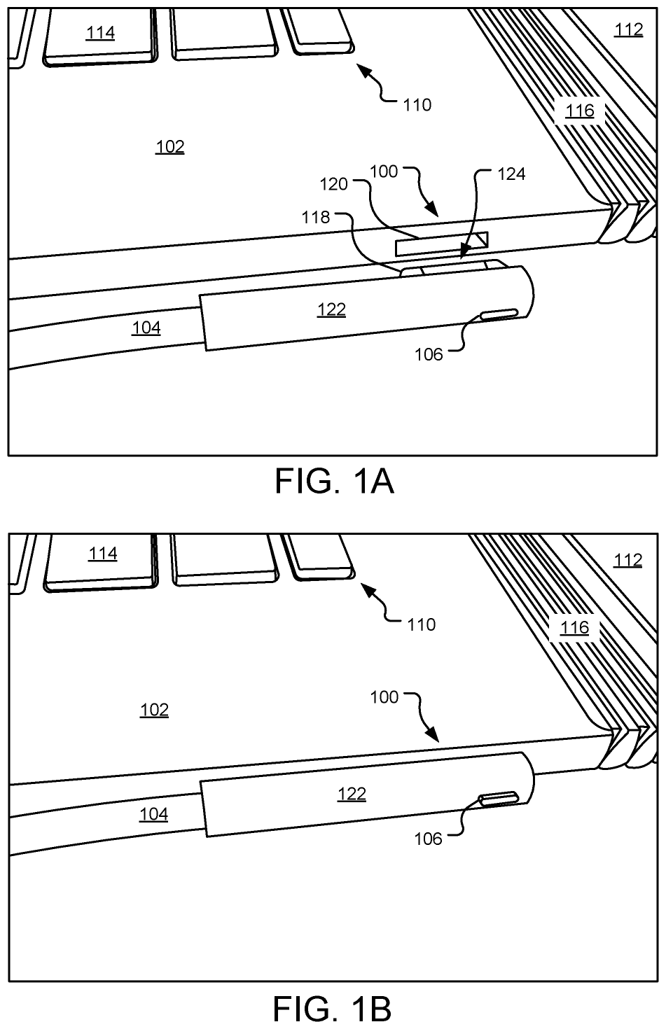

FIG. 1A illustrates a partial perspective view of a computing device 102 and associated cable 104 with a disconnected electrical connector 100 (or connector 100) incorporating a tactile electrical connection indicator (or tactile indicator) 106. The computing device 102 is illustrated as a laptop computer having a chassis containing a keypad 110 with an array of keys (e.g., key 114) arranged in a predetermined pattern (e.g., QWERTY) and a display 112 connected via hinge 116. Other electric devices, electronic devices, and/or computing devices may also adopt connector 100, or a functional variation thereof.

The connector 100 is an electromechanical device that creates an electrical connection between parts of a larger electrical circuit (here, the computing device 102 and a power supply, not shown), or between different electrical circuits, thereby joining them into the larger circuit via the cable 104. The connector 100 is selectively connected in that a first part of the connector 100 (e.g., a male portion or plug 118) is removable from a second part of the connector 100 (e.g., a female portion or socket 120). The connector 100 includes connector housing 122 and the plug 118 protrudes from the connector housing 122, which forms a first half of the connector 100. The computing device 102 chassis includes the socket 120, which forms a second half of the connector 100.

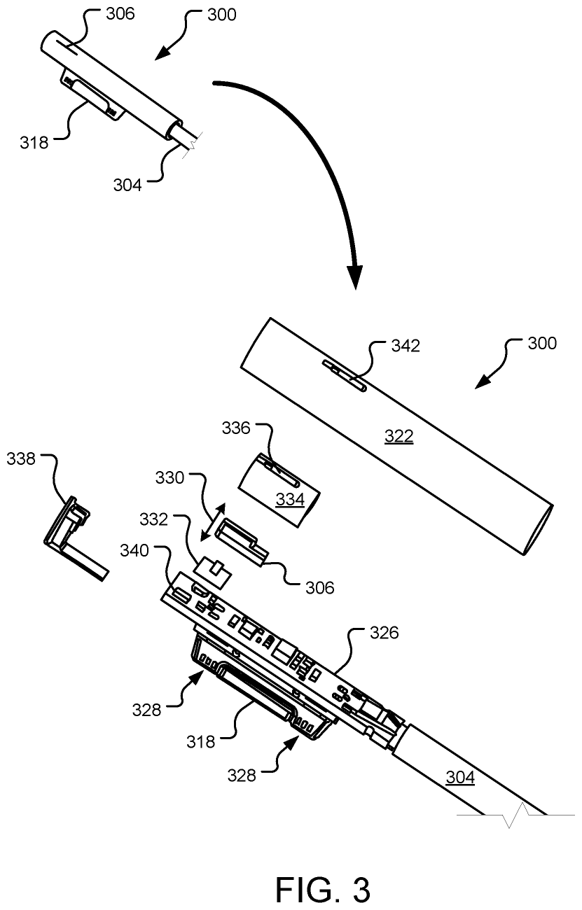

The plug 118 includes a set of electrical contacts (not shown, see e.g., electrical contacts 328 of FIG. 3) protruding from the connector housing 122 at a distal end 124 of the connector 100. The socket 120 includes a matched set of electrical contacts within the chassis of the computing device 102. The electrical contacts of the plug 118 and the socket 120 form a larger electrical circuit when brought together, as illustrated in FIG. 1B. The larger electrical circuit may be designed to carry data, power, or both over the connector 100.

The plug 118 is physically separated from the socket 120 in the disconnected position of FIG. 1A. Further, the tactile indicator 106 is illustrated as flush with a surrounding exterior surface of the connector housing 122 in the disconnected position of FIG. 1A. In other implementations, the tactile indicator 106 may be protruding from or recessed within the surrounding exterior surface of the connector housing 122 in the disconnected position.

FIG. 1B illustrates a partial perspective view of the computing device 102 and associated cable 104 of FIG. 1A, with the connector 100 incorporating the tactile indicator 106 connected. The tactile indicator 106 is illustrated as protruding from the surrounding exterior surface of the connector housing 122 in the connected position of FIG. 1B. In other implementations, the tactile indicator 106 may be flush with or recessed within the surrounding exterior surface of the connector housing 122 in the connected position. Regardless, the tactile indicator 106 is in a different position with reference to the surrounding exterior surface of the connector housing 122 in the connected position of FIG. 1B as compared to the disconnected position of FIG. 1A. This physical difference may be detected tactilely by a user running their finger(s) or other portion of the user's body over the tactile indicator 106, which offers a technical benefit to the user in that the user is not required to view the tactile indicator 106 to identify the physical difference. For users that are not visually impaired, the physical difference may also be visually detected.

In some implementations, the connector 100 and associated cable 104 extending therefrom functions as an adaptor. An opposing end of the cable 104 includes a second connector that allows the connector 100 and associated cable 104 to be selectively connected to a conventional connector and its associated cable. This allows a technical benefit in that the connector 100 and associated cable 104 to be easily retrofit to be used with electric devices that did not originally come so equipped. The adaptor implementation of the connector 100 and associated cable 104 may also afford additional physical space for internal components of the connector 100, as discussed below with reference to connector 300 of FIG. 3.

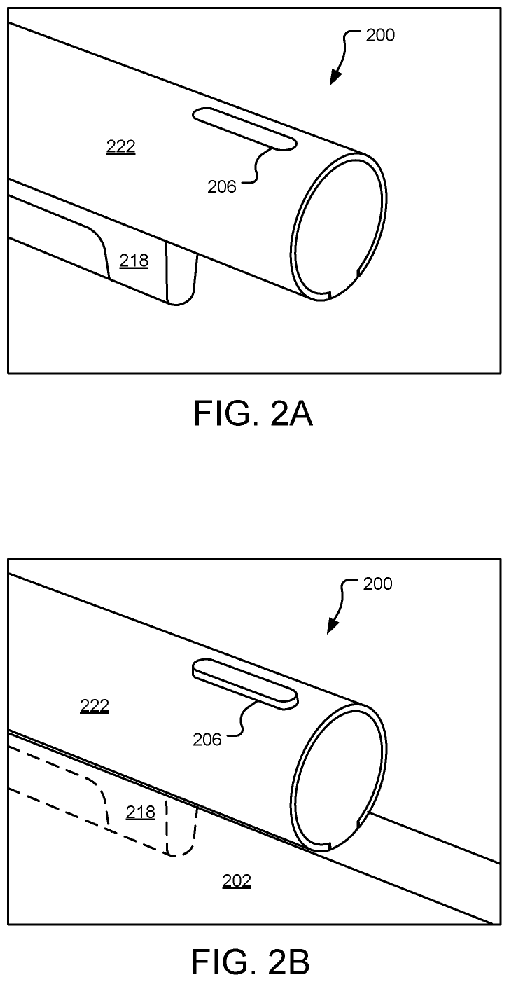

FIG. 2A illustrates a partial perspective view of an electrical connector 200 (or connector 200) incorporating a tactile electrical connection indicator (or tactile indicator) 206 in a disconnected position. The connector 200 is an electromechanical device that creates an electrical connection between parts of a larger electrical circuit (here, the computing device 202 and a power supply, not shown)), or between different electrical circuits, thereby joining them into the larger circuit. A first part of the connector 200 (e.g., a male portion or plug 218) is shown in FIG. 2A and is removable from a second part of the connector 200 (not shown, see e.g., socket 120 of FIGS. 1A and 1B).

The connector 200 includes connector housing 222 and the plug 218 protrudes from the connector housing 222, which forms the depicted first half of the connector 200. As noted above, a corresponding socket may form a second half of the connector 200. The plug 218 includes a set of electrical contacts (not shown, see e.g., electrical contacts 328 of FIG. 3) protruding from the connector housing 222 at the depicted distal end of the connector 200. The socket includes a matched set of electrical contacts. The electrical contacts of the plug 218 and the socket form a larger electrical circuit when brought together, as illustrated in FIG. 2B. The larger electrical circuit may be designed to carry data, power, or both over the connector 200.

The plug 218 is physically separated from the socket in the disconnected position of FIG. 2A. Further, the tactile indicator 206 is illustrated as flush with a surrounding exterior surface of the connector housing 222 in the disconnected position of FIG. 2A. In other implementations, the tactile indicator 206 may be protruding from or recessed within the surrounding exterior surface of the connector housing 222 in the disconnected position.

FIG. 2B illustrates a partial perspective view of the connector 200 incorporating the tactile indicator 206 of FIG. 2A in a connected position. The connector 200 is illustrated as connected in FIG. 2B with the plug 218 seated within a corresponding socket within the computing device 202. The plug 218 is illustrated in dashed lines as it is no longer visible from an exterior view of the connector 200.

The tactile indicator 206 is illustrated as protruding from the surrounding exterior surface of the connector housing 222 in the connected position of FIG. 2B. In other implementations, the tactile indicator 206 may be flush with or recessed within the surrounding exterior surface of the connector housing 222 in the connected position. Regardless, the tactile indicator 206 is in a different position with reference to the surrounding exterior surface of the connector housing 222 in the connected position of FIG. 2B as compared to the disconnected position of FIG. 2A. This physical difference may be detected tactilely by a user running their finger(s) or other portion of the user's body over the tactile indicator 206. For users that are not visually impaired, the physical difference may also be visually detected.

In some implementations, the tactile indicator 206 also includes a light-emitting diode (LED) or other light source. The LED illuminates in the connected position of FIG. 2B to visually emphasize the connected position that is also communicated tactilely. Similarly, the LED is unilluminated in the disconnected position of FIG. 2A to visually emphasize the disconnected position that is also communicated tactilely. This redundant communication of the connected position is technically advantageous in that it affords a greater swath of users access to the tactile indicator 206.

Further, the tactile indicator 206 may be secured to and sealed against the surrounding exterior surface of the connector housing 222 to meet the IPX5 or IPX6 in solid particle protection and IPX7 or IPX8 in in liquid ingress protection around and through the connector housing 222. Such sealing is technically advantageous in that reduces the likelihood of contamination within the connector housing 222 that could cause the connector 200 to cease functioning.

FIG. 3 illustrates a partial perspective view of an electrical connector 300 (or connector 300) incorporating a tactile electrical connection indicator (or tactile indicator) 306 and an enlarged and exploded view thereof. The connector 300 is an electromechanical device that creates an electrical connection between parts of a larger electrical circuit, or between different electrical circuits, thereby joining them into the larger circuit via cable 304. A first part of the connector 300 (e.g., a male portion or plug 318) is shown in FIG. 3 and is removable from a second part of the connector 300 (not shown, see e.g., socket 120 of FIGS. 1A and 1B).

The connector 300 is attached to a distal end of the cable 304 and includes a circuit board 326 with various microelectronic components that control various functionalities of the connector 300, including but not limited to that of the tactile indicator 306. The tactile indicator 306 is a solid protruding component that is moveable up and down with reference to the circuit board 326, as illustrated by arrow 330 when the connector 300 is assembled.

An actuator 332 is attached to and resides between the tactile indicator 306 and the circuit board 326 and provides motive force for moving the tactile indicator 306 up and down with reference to the circuit board 326. The circuit board 326 provides an electrical signal to the actuator 332 that defines what position the tactile indicator 306 should be in and the actuator 332 effects movement of the tactile indicator 306 to its the defined position. In an example implementation, the actuator 332 is a linear mechanical actuator, such as a muscle wire, electromagnetic actuator, or electromechanical switch that raises the tactile indicator 306 when power is supplied to the connector 300 via the cable 304 and biases the tactile indicator 306 to a lowered position when power is removed from the connector 300.

In some implementations, the tactile indicator 306 provides technical functionality beyond indicating the presence of a power supply. For example, the circuit board 326 may be capable of detecting an electrical connection on either side or both sides of the connector 300. For example, in an implementation that connects two electric devices (e.g., a computing device and a peripheral) via a USB-C connection, the circuit board 326 may be capable of detecting and distinguishing whether both, either, or neither of two electric devices are connected and communicate the status of that connection to the user. To that end, the connector 300 may be capable of receiving power via either end of the connector 300. The tactile indicator 306 may raise when both electric devices are connected, lower when neither of the electric devices are connected, and oscillate up and down when only one of the electric devices are connected, for example.

The circuit board 326 may further have smart functionality to take instructions from a connected electric device and communicate those instructions to a user via movement of the tactile indicator 306 (e.g., slow oscillation (pulsing), fast oscillation (vibrating), partial movements, and so on). For example, the tactile indicator 306 may oscillate to indicate to the user that the device is having a problem charging using the connector 300 (e.g., a charging error), regardless of whether the user has correctly electrically connected the connector 300. Other feedback features to be communicated from a connected electric device to the user via the tactile indicator 306 are contemplated herein. Different positions and oscillations of the tactile indicator 306 affords a variety of options for communicating information using physical positioning of the tactile indicator 306. A greater number of options yields a technical benefit in that it can communicate a greater quantity of information to the user.

Still further, the tactile indicator 306 may also function as a push button to allow the user to use the tactile indicator 306 as an input device. For example, the user may apply sufficient force to overcome the actuator 332 and depress an otherwise raised tactile indicator 306 to relay input instructions to a connected electric device via the circuit board 326. This may activate a functionality of the connected electric device (e.g., function as an on/off button or activate a narrator feature within the connected electric device's software). In some implementations, the tactile indicator 306 is an input device that may be programmable by the user to customize the user's experience using the connector 300 and associated electric device(s). Use of the tactile indicator 306 as a push button is technically advantageous in that it can combine functionalities into a singular structure, which can yield cost and space efficiency advantages.

In some implementations, at least the tactile indicator 306, the actuator 332, and a portion of the circuit board 326 could be combined together in a subassembly (referred to herein as a tactile indication module) that allows integration into a variety of applications where tactile feedback for charging or other electrical status is desired. For example, the subassembly could be adapted to the second part of the connector 300 (not shown, see e.g., socket 120 of FIGS. 1A and 1B rather than the depicted first part of the connector 300 (e.g., plug 318). Subassembly housing 334 may be used to contain the tactile indicator 306, the actuator 332, and a portion of the circuit board 326 together. The subassembly housing 334 includes an indicator aperture 336 that permits the tactile indicator 306 to move up and down with reference to the circuit board 326 and a portion of which through the subassembly housing 334.

The plug 318 includes at least one set of electrical contacts 328 that are electrically connected to the circuit board 326. The second part of the connector 300 (e.g., a socket, not shown) includes at least one matched set of electrical contacts (here, there are two sets on opposing ends of the plug 318). The electrical contacts of the plug 318 and the socket form a larger electrical circuit when brought together. The larger electrical circuit may be designed to carry data, power, or both over the connector 300.

The circuit board 326, plug 318, actuator 332, tactile indicator 306, subassembly housing 334, and any other components internal to the connector 300 are assembled within connector housing 322 and secured with cap cover 338, all of which forms the depicted first half of the connector 300. The plug 318 protrudes through a plug aperture (not shown) in the connector housing 322 and a portion of the tactile indicator 306 is visible through (and in some implementations and/or positions protruding though) an indicator aperture 342 in the connector housing 322 when the connector 300 is assembled. As noted above, a corresponding socket may form a second half of the connector 300.

When assembled, the actuator 332 is connected to the tactile indicator 306 and biases the tactile indicator 306 to a first position with reference to the connector housing 322 when the set of electrical contacts 328 are disconnected. The actuator 332 moves the tactile indicator 306 to a second position with reference to the connector housing 322 when the set of electrical contacts 328 are connected to corresponding electrical contacts of the corresponding socket. Biasing to the first position with reference to the connector housing 322 is technically advantageous in that it may communicate to the user that power is disconnected from the connector 300, even if a physical connection between the set of electrical contacts 328 and the corresponding electrical contacts of the corresponding socket is correctly made.

The tactile indicator 306 may be flush with a surrounding exterior surface of the connector housing 322 (referred to above as the first position) in the disconnected position of FIG. 3. In other implementations, the tactile indicator 306 may be protruding from or recessed within the surrounding exterior surface of the connector housing 322 in the disconnected position. The tactile indicator 206 may be protruding from the surrounding exterior surface of the connector housing 322 (referred to above as the second position) in a connected position (not shown, see e.g., FIGS. 1B and 2B). In other implementations, the tactile indicator 306 may be flush with or recessed within the surrounding exterior surface of the connector housing 322 in the connected position. Regardless, the tactile indicator 306 is in a different position with reference to the surrounding exterior surface of the connector housing 322 in the connected position as compared to the disconnected position. This physical difference may be detected tactilely by a user running their finger(s) or other portion of the user's body over the tactile indicator 306. For users that are not visually impaired, the physical difference may also be visually detected.

In some implementations, the connector 300 also includes a light-emitting diode (LED) or other light source for the tactile indicator 306. One or more LEDs 340 are mounted on the circuit board 326 that illuminate in the connected position (e.g., when power is supplied to the connector 300 via the cable 304) and de-illuminate in the disconnected position (e.g., when power is removed from the connector 300). The tactile indicator 306 may further function as a light pipe to direct light generated by the LEDs 340 upward through the tactile indicator 306 so that the portion of the tactile indicator 306 that is visible through the indicator aperture 342 may be illuminated by the LEDs 340. The subassembly housing 334 may further function as a light cover, thereby directing light generated by the LEDs 340 to the tactile indicator 306 and blocking the light from emanating in other directions. The LEDs 340 may further serve to power the actuator 332.

The LEDs 340 illuminate in the connected position of FIGS. 1B and 2B to visually emphasize the connected position that is also communicated tactilely by the tactile indicator 306. Similarly, the LEDs 340 are unilluminated in the disconnected position of FIG. 3 to visually emphasize the disconnected position that is also communicated tactilely by the tactile indicator 306. In some implementations, the feedback and smart functionalities discussed above using oscillation patterns of the tactile indicator 306 may be mirrored by flashing patterns or colors of the LEDs.

In some implementations, the actuator 332 and/or the tactile indicator 306 may make an audibly perceptible noise (e.g., a click) when moving that serves to audially emphasize that which is also communicated tactilely by the tactile indicator 306. In some implementations, the feedback and smart functionalities discussed above using oscillation patterns of the tactile indicator 306 may be audially emphasized using the audibly perceptible noise from the actuator 332. This redundant communication of the connected position is technically advantageous in that it affords a greater swath of users access to the tactile indicator 306, particularly those unable to see or touch the tactile indicator 306.

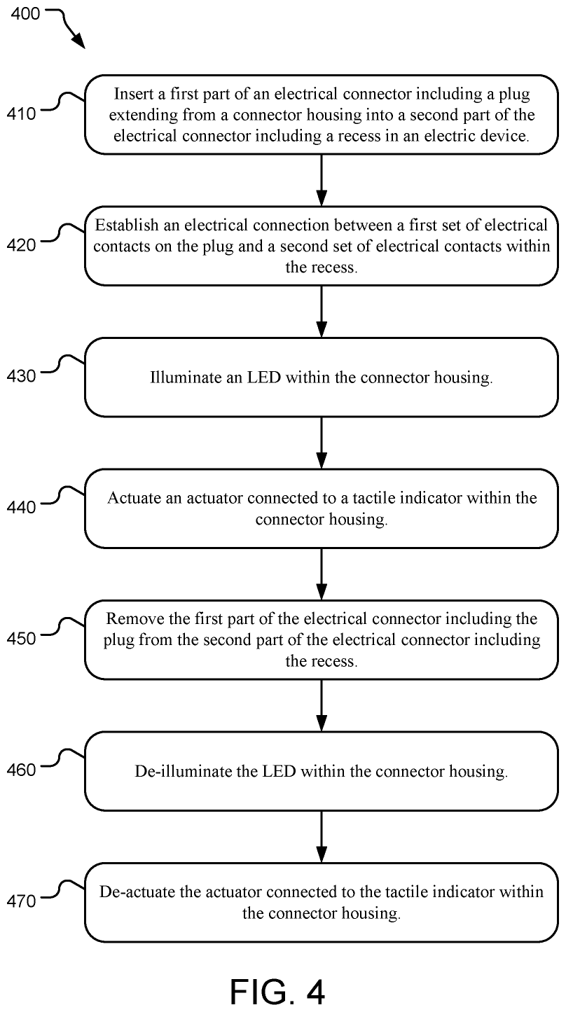

FIG. 4 illustrates example operations 400 for using an electrical connector incorporating a tactile electrical connection indicator. An insertion operation 410 inserts a first part of the electrical connector including a plug extending from a connector housing at a distal end of a cable into a second part of the electrical connector including a recess in an electric device. The insertion operation 410 is performed physically by a user plugging the first part of the electrical connector into the second part of the electrical connector.

An establishing operation 420 establishes an electrical connection between a first set of electrical contacts on the plug and a second set of electrical contacts within the recess. The first set of electrical contacts are matched to the second set of electrical contacts and the establishing operation 420 is responsive to the insertion operation 410 but may occur simultaneously or nearly simultaneously with the insertion operation 410.

An illuminating operation 430 illuminates an LED within the connector housing. In some implementations, the LED is omitted from the connector housing and thus the illuminating operation 430 is not performed. An actuating operation 440 actuates an actuator connected to a tactile indicator within the connector housing. The actuator moves the tactile indicator to a connected position with reference to the connector housing. The illuminating operation 430 and/or the actuating operation 440 are responsive to the establishing operation 420 but may occur simultaneously or nearly simultaneously with the establishing operation 420.

A removing operation 450 removes the first part of the electrical connector including the plug from the second part of the electrical connector including the recess. The removing operation 450 is performed physically by a user pulling or otherwise dislodging the first part of the electrical connector from the second part of the electrical connector. The removing operation 450 further disconnects the electrical connection between the first set of electrical contacts on the plug and the second set of electrical contacts within the recess.

A de-illuminating operation 460 de-illuminates the LED within the connector housing. In some implementations, the LED is omitted from the connector housing and thus the de-illuminating operation 460 is not performed. A de-actuating operation 470 de-actuates the actuator connected to the tactile indicator within the connector housing. The actuator moves the tactile indicator to a disconnected position with reference to the connector housing. The de-illuminating operation 460 and/or the de-actuating operation 470 are responsive to the removing operation 450 but may occur simultaneously or nearly simultaneously with the removing operation 450.

The operations making up the embodiments of the invention described herein are referred to variously as operations, steps, objects, or modules. Furthermore, the operations may be performed in any order, adding or omitting operations as desired, unless explicitly claimed otherwise or a specific order is inherently necessitated by the claim language.

In various implementations, the presently disclosed technology includes an electrical connector comprising: a connector housing; a set of electrical contacts within the connector housing and at a distal end of the electrical connector; a tactile indicator selectively moveable with reference to the connector housing; and a circuit board controlling an actuator, wherein the actuator is connected to the tactile indicator and biases the tactile indicator to a first position with reference to the connector housing when the set of electrical contacts are disconnected, the actuator to move the tactile indicator to a second position with reference to the connector housing when the set of electrical contacts are connected.

The tactile indicator may provide a tactile indication of an electrical connection with an electric device through the electrical connector.

The tactile indicator may provide a tactile indication of a connection between a power supply and an electric device through the electrical connector.

The electric device may be a computing device.

The first position may be one of recessed within, flush with, and protruding from an exterior surface of the connector housing.

The second position may also be one of recessed into, flush with, and protruding from the exterior surface of the connector housing, wherein the second position differs from the first position.

The electrical connector may further include a second set of electrical contacts, the actuator to move the tactile indicator to the second position with reference to the connector housing when the set of electrical contacts are connected to the second set of electrical contacts.

The set of electrical contacts may be that of a plug and the second set of electrical contacts may be that of a socket.

The set of electrical contacts may be selectively removable from the second set of electrical contacts.

The tactile indicator may include a light-emitting diode (LED), wherein the LED illuminates when the set of electrical contacts are connected.

The circuit board may take instructions from a connected electric device and may relay the instructions to a user via the tactile indicator.

The instructions may include oscillating the tactile indicator up and down.

The tactile indicator may be a push button to relay input instructions from a user to a connected electric device via the circuit board.

The actuator or the tactile indicator may make an audibly perceptible noise when moving.

The actuator may oscillate the tactile indicator up and down to indicate a state of charge of an electric device connected via the electrical connector.

The actuator may bias the tactile indicator to the first position when the electrical connector is unpowered.

In various implementations, the presently disclosed technology includes a method of using an electrical connector comprising: inserting a first part of the electrical connector including a plug extending from a connector housing at a distal end of a cable into a second part of the electrical connector including a recess in an electric device; establishing an electrical connection between a first set of electrical contacts on the plug and a second set of electrical contacts within the recess, the establishing operation responsive to the inserting operation; and actuating an actuator connected to a tactile indicator within the connector housing, the actuator to move the tactile indicator to a connected position with reference to the connector housing, the actuating operation responsive to the establishing operation.

The method may further include removing the first part of the electrical connector including the plug from the second part of the electrical connector including the recess, thereby disconnecting the electrical connection between the first set of electrical contacts on the plug and the second set of electrical contacts within the recess; and de-actuating the actuator connected to the tactile indicator within the connector housing, the actuator to move the tactile indicator to a disconnected position with reference to the connector housing, the de-actuating operation responsive to the removing operation.

The method may further include illuminating an LED within the connector housing responsive to the establishing operation; and de-illuminating the LED responsive to the removing operation.

In various implementations, the presently disclosed technology includes an electrical connector comprising: a first part of the electrical connector comprising a recess in a computing device and a first set of electrical contacts within the recess; and a second part of the electrical connector. The second part comprising: a connector housing; a second set of electrical contacts within the connector housing and at a distal end of the electrical connector; a tactile indicator selectively moveable with reference to the connector housing; and a circuit board controlling an actuator, wherein the actuator is connected to the tactile indicator and biases the tactile indicator to a first position with reference to the connector housing when the first set is disconnected from the second set of electrical contacts, the actuator to move the tactile indicator to a second position with reference to the connector housing when the first set is connected to the second set of electrical contacts.

The above specification, examples, and data provide a complete description of the structure and use of exemplary embodiments of the invention. Since many embodiments of the invention can be made without departing from the spirit and scope of the invention, the invention resides in the claims hereinafter appended. Furthermore, structural features of the different embodiments may be combined in yet another embodiment without departing from the recited claims.

What is claimed is:

1. An electrical connector comprising:
a connector housing;
a set of electrical contacts within the connector housing and at a distal end of the electrical connector;
a tactile indicator selectively moveable with reference to the connector housing; and
a circuit board controlling an actuator, wherein the actuator is connected to the tactile indicator and biases the tactile indicator to a first position with reference to the connector housing when the set of electrical contacts are disconnected, the actuator to move the tactile indicator to a second position with reference to the connector housing when the set of electrical contacts are connected.

2. The electrical connector of claim 1, wherein the tactile indicator provides a tactile indication of an electrical connection with an electric device through the electrical connector.

3. The electrical connector of claim 1, wherein the tactile indicator provides a tactile indication of a connection between a power supply and an electric device through the electrical connector.

4. The electrical connector of claim 3, wherein the electric device is a computing device.

5. The electrical connector of claim 1, wherein the first position is one of recessed within, flush with, and protruding from an exterior surface of the connector housing.

6. The electrical connector of claim 5, wherein the second position is also one of recessed into, flush with, and protruding from the exterior surface of the connector housing, and wherein the second position differs from the first position.

7. The electrical connector of claim 1, further comprising:
a second set of electrical contacts, the actuator to move the tactile indicator to the second position with reference to the connector housing when the set of electrical contacts are connected to the second set of electrical contacts.

8. The electrical connector of claim 7, wherein the set of electrical contacts are that of a plug and the second set of electrical contacts are that of a socket.

9. The electrical connector of claim 7, wherein the set of electrical contacts are selectively removable from the second set of electrical contacts.

10. The electrical connector of claim 1, wherein the tactile indicator includes a light-emitting diode (LED), wherein the LED illuminates when the set of electrical contacts are connected.

11. The electrical connector of claim 1, wherein the circuit board is to take instructions from a connected electric device and relay the instructions to a user via the tactile indicator.

12. The electrical connector of claim 11, wherein the instructions include oscillating the tactile indicator up and down.

13. The electrical connector of claim 1, wherein the tactile indicator is a push button to relay input instructions from a user to a connected electric device via the circuit board.

14. The electrical connector of claim 1, wherein the actuator or the tactile indicator is to make an audibly perceptible noise when moving.

15. The electrical connector of claim 1, wherein the actuator is to oscillate the tactile indicator up and down to indicate a state of charge of an electric device connected via the electrical connector.

16. The electrical connector of claim 1, wherein the actuator is to bias the tactile indicator to the first position when the electrical connector is unpowered.

17. A method of using an electrical connector comprising:
inserting a first part of the electrical connector including a plug extending from a connector housing at a distal end of a cable into a second part of the electrical connector including a recess in an electric device;
establishing an electrical connection between a first set of electrical contacts on the plug and a second set of electrical contacts within the recess, the establishing operation responsive to the inserting operation; and
actuating an actuator connected to a tactile indicator within the connector housing, the actuator to move the tactile indicator to a connected position with reference to the connector housing, the actuating operation responsive to the establishing operation.

18. The method of claim 17, further comprising:
removing the first part of the electrical connector including the plug from the second part of the electrical connector including the recess, thereby disconnecting the electrical connection between the first set of electrical contacts on the plug and the second set of electrical contacts within the recess; and
de-actuating the actuator connected to the tactile indicator within the connector housing, the actuator to move the tactile indicator to a disconnected position with reference to the connector housing, the de-actuating operation responsive to the removing operation.

19. The method of claim 18, further comprising:
illuminating an LED within the connector housing responsive to the establishing operation; and
de-illuminating the LED responsive to the removing operation.

20. An electrical connector comprising:
a first part of the electrical connector comprising:
a recess in a computing device; and
a first set of electrical contacts within the recess; and
a second part of the electrical connector comprising:
a connector housing;
a second set of electrical contacts within the connector housing and at a distal end of the electrical connector;
a tactile indicator selectively moveable with reference to the connector housing; and
a circuit board controlling an actuator, wherein the actuator is connected to the tactile indicator and biases the tactile indicator to a first position with reference to the connector housing when the first set is disconnected from the second set of electrical contacts, the actuator to move the tactile indicator to a second position with reference to the connector housing when the first set is connected to the second set of electrical contacts.
